(19) United States
(12) Patent Application Publication
(10) Pub. No.: US 2026/0313805 A1
(43) Pub. Date: Oct. 8, 2026

(54) POWER MODULE AND METHOD FOR MANUFACTURING THE SAME, AND POWER CONVERSION APPARATUS

(71) Applicant: MITSUBISHI ELECTRIC CORPORATION, Tokyo (JP)

(72) Inventor: Yusaku ITO, Chiyoda-ku, Tokyo (JP)

(73) Assignee: MITSUBISHI ELECTRIC CORPORATION, Tokyo (JP)

(21) Appl. No.: 19/491,470

(22) PCT Filed: Jul. 3, 2023
(86) PCT No.: PCT/JP2023/024607

§ 371 Date: Dec. 9, 2025

(51) Int. Cl. H05K 1/181; H05K 3/32

(52) U.S. Cl. CPC H05K 1/181; H05K 3/32; H05K 2201/10272; H05K 2201/10287

(57) ABSTRACT

A power module comprises a circuit board, a semiconductor device, a terminal, and a conductive connection member. The circuit board includes an insulating layer having a major surface, and a conductive circuit pattern provided on the major surface. The semiconductor device is joined to the conductive circuit pattern. The conductive circuit pattern includes a conductive pattern. The terminal includes a first end. The first end of the terminal includes a first surface joined to the conductive pattern and a second surface opposite to the first surface. The conductive connection member bridges the second surface of the terminal and the conductive pattern.

### TECHNICAL FIELD

The present disclosure relates to a power module and a method for manufacturing the same, and a power conversion apparatus.

### BACKGROUND ART

Japanese Patent Laying-Open No. 2001-237359 (PTL 1) discloses a power semiconductor device comprising a semiconductor chip, a terminal metal fitting, and a resin casing frame to which the terminal metal fitting is secured. The terminal metal fitting includes a first electrode and a second electrode disposed at a distal end of the terminal metal fitting with respect to the first electrode. This power semiconductor device allows electrical connection between the semiconductor chip and the terminal metal fitting to be selected between soldering between the second electrode and the semiconductor chip and a bonding wire between the first electrode and the semiconductor chip.

### CITATION LIST

### Patent Literature

PTL 1: Japanese Patent Laying-Open No. 2001-237359

### SUMMARY OF INVENTION

### Technical Problem

It is an object of the present disclosure to provide a power module and a power conversion apparatus improved in reliability.

### Solution to Problem

According to the present disclosure, a power module comprises a circuit board, a semiconductor device, a terminal, and a first conductive connection member. The circuit board includes an insulating layer having a major surface and a conductive circuit pattern provided on the major surface. The semiconductor device is joined to the conductive circuit pattern. The conductive circuit pattern includes a first conductive pattern. The terminal includes a first end. The first end of the terminal includes a first surface joined to the first conductive pattern and a second surface opposite to the first surface. The first conductive connection member bridges the second surface and the first conductive pattern.

According to the present disclosure, a method for manufacturing a power module comprises preparing a circuit board. The circuit board includes an insulating layer having a major surface, and a conductive circuit pattern provided on the major surface. The conductive circuit pattern includes a first conductive pattern. The method for manufacturing a power module according to the present embodiment comprises joining a semiconductor device to the conductive circuit pattern and joining a terminal to the first conductive pattern. The terminal includes a first end. The first end of the terminal includes a first surface joined to the first conductive pattern and a second surface opposite to the first surface. The method for manufacturing a power module according to the present embodiment comprises bridging the second surface and the first conductive pattern with a first conductive connection member.

According to the present disclosure, a power conversion apparatus comprises: a main conversion circuit having the power module according to the present disclosure to convert received power and output the converted power; and a control circuit to output a control signal to the main conversion circuit to control the main conversion circuit.

### Advantageous Effects of Invention

The terminal is electrically connected to the first conductive pattern not only by a joint between the first surface of the terminal and the first conductive pattern but also by the first conductive connection member. Therefore, even if the joint peels off the first conductive pattern, the terminal is still electrically connected to the first conductive pattern through the first conductive connection member. The presently disclosed power module and power conversion apparatus are improved in reliability.

### BRIEF DESCRIPTION OF DRAWINGS

FIG. 1 is a schematic cross section of a power module according to a first embodiment.

FIG. 2 is a schematic, partially enlarged perspective view of the power module according to the first embodiment.

FIG. 3 is a schematic, partially enlarged plan view of the power module according to the first embodiment.

FIG. 4 is a flowchart of a method for manufacturing the power module according to the first embodiment.

FIG. 5 is a schematic, partially enlarged perspective view of a power module according to a variation of the first embodiment.

FIG. 6 is a schematic, partially enlarged plan view of the power module according to the variation of the first embodiment.

FIG. 7 is a schematic, partially enlarged plan view of a power module according to a second embodiment.

FIG. 8 is a schematic, partially enlarged plan view of a power module according to a first variation of the second embodiment.

FIG. 9 is a schematic, partially enlarged plan view of a power module according to a second variation of the second embodiment.

FIG. 10 is a schematic, partially enlarged plan view of a power module according to a third embodiment.

FIG. 11 is a schematic, partially enlarged perspective view of the power module according to the third embodiment.

FIG. 12 is a block diagram for illustrating a configuration of a power conversion system according to a fourth embodiment.

### DESCRIPTION OF EMBODIMENTS

Hereinafter, embodiments of the present disclosure will be described. Note that any identical configuration will be identically denoted and will not be described repeatedly.

### First Embodiment

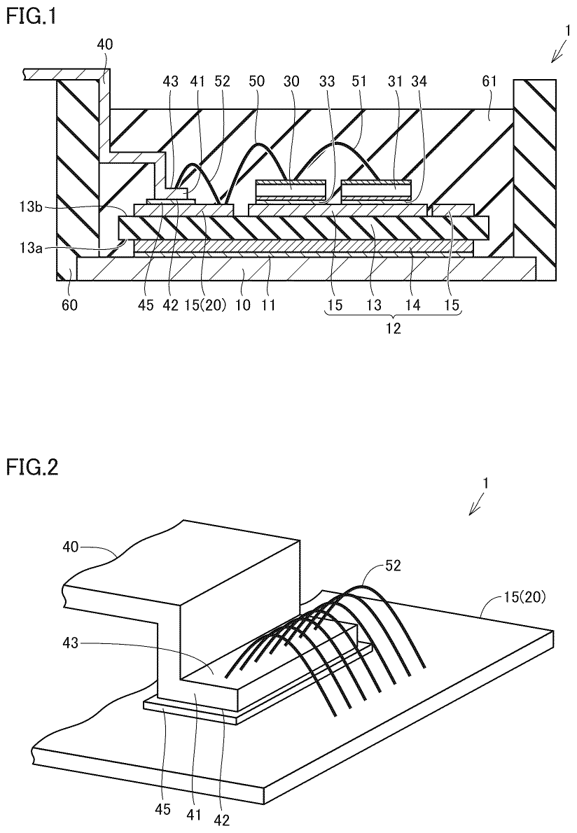

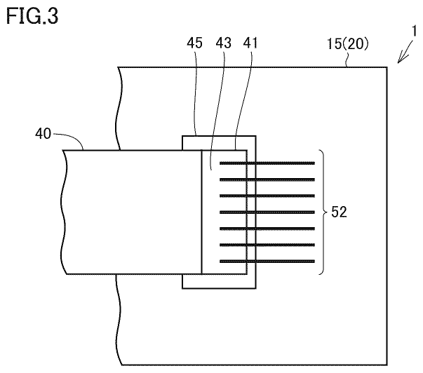

A power module 1 according to a first embodiment will now be described with reference to FIGS. 1 to 3. Power module 1 comprises a circuit board 12, semiconductor devices 30 and 31, a terminal 40, and conductive connection members 50, 51 and 52. Power module 1 may further comprise a base plate 10, a casing 60, and a sealing member 61.

Base plate 10 supports circuit board 12. Power module 1 generates heat, and base plate 10 dissipates the heat out of power module 1. Base plate 10 is formed for example of copper (Cu), a silicon carbide particle-reinforced aluminum composite material (AlSiC), or the like. Base plate 10 may be provided with a cooling fin (not shown).

Circuit board 12 includes an insulating layer 13 and a conductive circuit pattern 15. Circuit board 12 may further include a conductor pattern 14.

Insulating layer 13 is formed for example of an insulating material such as alumina (Al₂O₃), aluminum nitride (AlN), resin, or a filler-containing resin. Insulating layer 13 has a major surface 13a and a major surface 13b opposite to major surface 13a.

Conductor pattern 14 is provided on major surface 13a. Conductive circuit pattern 15 is provided on major surface 13b. Conductive circuit pattern 15 includes a conductive pattern 20. Conductive pattern 20 is for example a joining conductive pad to which terminal 40 is joined. Conductive pattern 20 may be spaced from that portion of conductive circuit pattern 15 to which semiconductor devices 30 and 31 are joined. Conductor pattern 14 and conductive circuit pattern 15 are formed of a conductive material such as copper (Cu) or aluminum (Al). Conductor pattern 14 and conductive circuit pattern 15 may have a two-layer structure including an aluminum (Al) layer in contact with insulating layer 13 and a copper (Cu) layer provided on the aluminum (Al) layer. Conductive circuit pattern 15 has a surface provided with a structure or coating of irregularities for enhanced adhesion between conductive circuit pattern 15 and sealing member 61.

Circuit board 12 is fixed to base plate 10 at a joint 11. Specifically, conductor pattern 14 is joined to base plate 10 at joint 11. Joint 11 may be formed for example of solder, a fine silver particulate sintered compact or a similar fine metallic particulate sintered compact, or a conductive filler-containing resin or the like, or may be liquid phase diffusion bonding between conductor pattern 14 and base plate 10.

Semiconductor devices 30 and 31 are, for example, power semiconductor devices. Specifically, semiconductor devices 30 and 31 are switching devices such as insulated gate bipolar transistors (IGBTs) or metal oxide semiconductor field effect transistors (MOSFETs), or rectifier devices such as Schottky barrier diodes. Semiconductor devices 30 and 31 are formed of silicon (Si) or a wide bandgap semiconductor material having a bandgap larger than silicon (Si). The wide bandgap semiconductor material is, for example, silicon carbide (SiC), a gallium nitride (GaN)-based material, diamond, or the like. Semiconductor devices 30 and 31 formed of the wide bandgap semiconductor material improve their allowable current density and reduce their power loss. This allows power module 1 to be miniaturized.

Semiconductor devices 30 and 31 have electrodes. Semiconductor devices 30 and 31 have the electrodes formed for example of aluminum (Al) or a silicon (Si)-added aluminum alloy. A coating layer such as a nickel (Ni) layer or a gold (Au) layer may be provided on the electrodes of semiconductor devices 30 and 31.

Semiconductor device 30 is joined to conductive circuit pattern 15 at a joint 33. Semiconductor device 31 is joined to conductive circuit pattern 15 at a joint 34. Joints 33 and 34 may be formed for example of solder, a fine silver particulate sintered compact or a similar fine metallic particulate sintered compact, or a conductive filler-containing resin or the like, or may be liquid phase diffusion bonding between the electrodes of semiconductor devices 30 and 31 and conductive circuit pattern 15.

Terminal 40 extends to an outside of casing 60. A current from power module 1 is extracted out of power module 1 through terminal 40. Terminal 40 is formed for example of a conductive material such as copper (Cu) or aluminum (Al). A coating layer (not shown) such as a nickel (Ni) layer or a gold (Au) layer may be provided on a surface of terminal 40.

Terminal 40 includes a first end 41. First end 41 is an end of terminal 40 that is proximal to circuit board 12. First end 41 includes a first surface 42 and a second surface 43 opposite to first surface 42. Terminal 40 has first surface 42 joined to conductive pattern 20 at a joint 45. Joint 45 may be formed for example of solder, a fine silver particulate sintered compact or a similar fine metallic particulate sintered compact, or a conductive filler-containing resin or the like, or may be liquid phase diffusion bonding between first surface 42 of terminal 40 and conductive pattern 20.

As shown in FIG. 1, in the present embodiment, terminal 40 is an outsert-type terminal separatable from casing 60. Terminal 40 may be an insert-type terminal integrated with casing 60.

Conductive connection members 50, 51, and 52 are formed of a conductive material such as aluminum (Al) or copper (Cu). Conductive connection member 50 bridges semiconductor device 30 and conductive pattern 20. Conductive connection member 50 is for example a conductive wire bonded to an electrode of semiconductor device 30 and conductive pattern 20. Conductive connection member 50 may be a conductive plate joined to an electrode of semiconductor device 30 and conductive pattern 20 using a joint member such as solder. Conductive connection member 51 bridges semiconductor devices 30 and 31. Conductive connection member 51 is for example a conductive wire bonded to an electrode of semiconductor device 30 and an electrode of semiconductor device 31.

Conductive connection member 52 bridges conductive pattern 20 and second surface 43 of first end 41 of terminal 40. Conductive connection member 52 is for example a conductive wire bonded to conductive pattern 20 and second surface 43 of first end 41 of terminal 40.

Casing 60 protects circuit board 12 and semiconductor devices 30 and 31. Casing 60 is fixed to base plate 10 with an adhesive (not shown). Casing 60 is formed for example of an insulating resin such as epoxy resin or polyphenylene sulfide resin.

Sealing member 61 seals semiconductor devices 30 and 31. Sealing member 61 is formed for example of epoxy resin or a similar thermosetting resin, silicon gel, or a metal or filler-containing, insulating resin. Semiconductor devices 30 and 31 formed of the wide bandgap semiconductor material may attain a high temperature of about 200 °C while semiconductor devices 30 and 31 in operation. Sealing member 61 formed of the metal or filler-containing, insulating resin is prevented from being softened or deteriorated even at such a high temperature. This can prevent reduction in reliability of joints of conductive connection members 50, 51, and 52.

Sealing member 61 may have a multi-layer structure including a first sealing layer (not shown) covering joints between semiconductor devices 30 and 31 and conductive connection members 50 and 51, and a second sealing layer (not shown) provided on the first sealing layer, circuit board 12, semiconductor devices 30 and 31, and base plate 10. The first sealing layer is formed of a material harder than the second sealing layer, and reinforces the joints between semiconductor devices 30 and 31 and conductive connection members 50 and 51. For example, the first scaling layer is formed of epoxy resin, and the second sealing layer is formed of gel or the like.

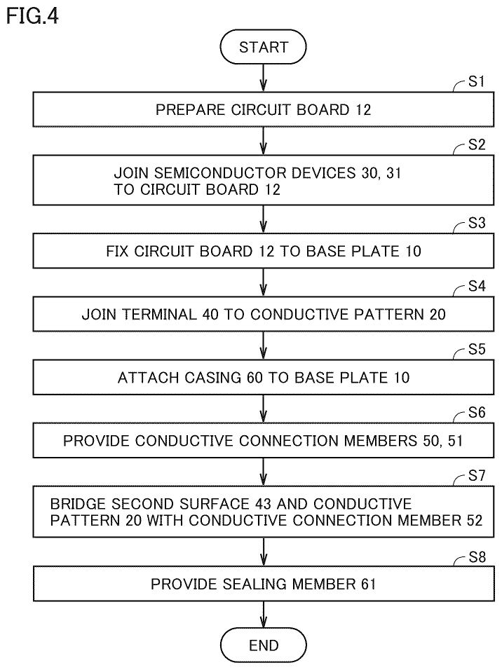

An example of a method for manufacturing power module 1 according to the present embodiment will now be described with reference to FIG. 4. The method for manufacturing power module 1 according to the present embodiment comprises preparing circuit board 12 (S1). Circuit board 12 includes insulating layer 13 and conductive circuit pattern 15. Insulating layer 13 has major surface 13b. Conductive circuit pattern 15 is provided on major surface 13b. Conductive circuit pattern 15 includes conductive pattern 20. Circuit board 12 may further include conductor pattern 14.

The method for manufacturing power module 1 according to the present embodiment includes joining semiconductor devices 30 and 31 to circuit board 12 (S2). Semiconductor devices 30 and 31 are joined to conductive circuit pattern 15 at joints 33 and 34.

The method for manufacturing power module 1 according to the present embodiment includes fixing circuit board 12 to base plate 10 (S3). Circuit board 12 has conductor pattern 14 joined to base plate 10 at joint 11.

The method for manufacturing power module 1 according to the present embodiment includes joining terminal 40 to conductive pattern 20 (S4), Terminal 40 includes first end 41. First end 41 of terminal 40 includes first surface 42 and second surface 43 opposite to first surface 42. First surface 42 is joined to conductive pattern 20. Joint 45 between terminal 40 and conductive pattern 20 may be formed for example of solder, a fine silver particulate sintered compact or a similar fine metallic particulate sintered compact, or a conductive filler-containing resin or the like, or may be liquid phase diffusion bonding between first surface 42 of terminal 40 and conductive pattern 20.

The method for manufacturing power module 1 according to the present embodiment includes attaching casing 60 to base plate 10 (S5). Casing 60 is fixed to base plate 10 with an adhesive (not shown).

The method for manufacturing power module 1 according to the present embodiment includes providing conductive connection members 50 and 51 (S6). Conductive connection member 50 bridges conductive pattern 20 and semiconductor device 30. Conductive connection member 50 is connected to conductive pattern 20 and semiconductor device 30. When conductive connection member 50 is a conductive wire, the conductive wire is bonded to conductive pattern 20 and semiconductor device 30. Conductive connection member 50 bridges semiconductor devices 30 and 31. Conductive connection member 51 is connected to semiconductor devices 30 and 31. When conductive connection member 51 is a conductive wire, the conductive wire is bonded to semiconductor devices 30 and 31.

The method for manufacturing power module 1 according to the present embodiment includes bridging second surface 43 of terminal 40 and conductive pattern 20 with conductive connection member 52 (S7). Conductive connection member 52 is connected to second surface 43 of terminal 40 and conductive pattern 20. When conductive connection member 52 is a conductive wire, the conductive wire is bonded to second surface 43 of terminal 40 and conductive pattern 20.

The method for manufacturing power module 1 according to the present embodiment includes providing sealing member 61 (S8). For example, sealing member 61 is provided by applying a sealing material in a space surrounded by casing 60 and base plate 10.

As has been set forth above, sealing member 61 may have a multi-layer structure including a first sealing layer (not shown) and a second sealing layer (not shown). For example, sealing member 61 having the multi-layer structure may be formed by applying a first sealing material to connections between semiconductor devices 30 and 31 and conductive connection members 50 and 51, and subsequently applying a second sealing material on the first sealing material, circuit board 12, semiconductor devices 30 and 31, and base plate 10.

A variation of the method for manufacturing power module 1 according to the present embodiment will now be described. Steps S2 and S3 may be performed simultaneously. Step S3 may be performed before step S2. When conductive connection members 50, 51, and 52 are identical conductive connection members, steps S6 and S7 may be performed simultaneously.

A function of power module 1 according to the present embodiment will now be described. While power module 1 is in operation, semiconductor devices 30 and 31 generate heat, and semiconductor devices 30 and 31, terminal 40, and joint 45 will be high in temperature. In contrast, while power module 1 is not in operation, semiconductor devices 30 and 31 do not generate heat, and semiconductor devices 30 and 31, terminal 40, and joint 45 will be low in temperature. Such a temperature cycle applies thermal stress to joint 45 repeatedly. A crack is caused from an end of joint 45, and the crack develops into joint 45. This may peel joint 45 off conductive pattern 20.

However, power module 1 has terminal 40 electrically connected to conductive pattern 20 not only by joint 45 but also by conductive connection member 52. Conductive connection member 52 bridges second surface 43 of terminal 40 and conductive pattern 20 and is deformable. Conductive connection member 52 deforms in response to the temperature cycle, and accordingly, thermal stress acting on a joint between conductive connection member 52 and terminal 40 and a joint between conductive connection member 52 and conductive pattern 20 is small. The joint between conductive connection member 52 and terminal 40 and the joint between conductive connection member 52 and conductive pattern 20 have higher durability against the temperature cycle than joint 45 does. Therefore, even if joint 45 peels off conductive pattern 20, terminal 40 is still electrically connected to conductive pattern 20 through conductive connection member 52. This can prevent power module 1 from failing.

Furthermore, a portion of a current flowing through power module 1 flows through conductive connection member 52, and this reduces a current flowing through joint 45. This suppresses an increase of the temperature of joint 45 caused while power module 1 is in operation, and joint 45 is less likely to peel off conductive pattern 20. This can suppress failure of power module 1.

When terminal 40, conductive pattern 20, and conductive connection member 52 are formed of the same material, thermal stress acting on the joint between conductive connection member 52 and terminal 40 and the joint between conductive connection member 52 and conductive pattern 20 is further reduced. Therefore, even if joint 45 peels off conductive pattern 20, terminal 40 is still electrically connected to conductive pattern 20 through conductive connection member 52. This can prevent power module 1 from failing.

When terminal 40, conductive pattern 20, and conductive connection member 52 are formed of copper (Cu), terminal 40, conductive pattern 20, and conductive connection member 52 are equal in hardness. Therefore, even when conductive connection member 52 is joined to terminal 40 and conductive pattern 20 by ultrasonic bonding, conductive connection member 52 does not perforate terminal 40 or conductive pattern 20, and conductive connection member 52 is thus satisfactorily joined to terminal 40 and conductive pattern 20. This enhances the joint between conductive connection member 52 and terminal 40 and the joint between conductive connection member 52 and conductive pattern 20 in reliability. This in turn enhances power module 1 in reliability.

Joint 45 has a joint area larger than that between terminal 40 and conductive connection member 52 and that between conductive connection member 52 and conductive pattern 20. When there is no crack in joint 45, the electrical resistance between terminal 40 and conductive pattern 20 via joint 45 is smaller than that between terminal 40 and conductive pattern 20 via conductive connection member 52. When a crack develops in joint 45, the electrical resistance between terminal 40 and conductive pattern 20 increases. Furthermore, when joint 45 peels off conductive pattern 20, the electrical resistance between terminal 40 and conductive pattern 20 rapidly increases. For example, the electrical resistance between a portion of terminal 40 extending out of casing 60 and conductive pattern 20 can be monitored to detect deterioration of joint 45.

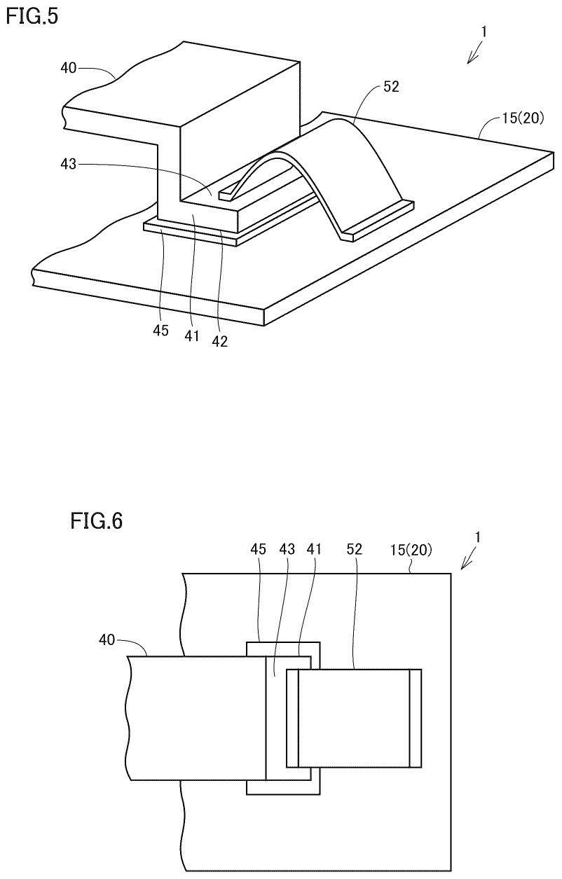

Power module 1 according to a variation of the present embodiment will now be described. As shown in FIGS. 5 and 6, conductive connection member 52 may be a conductive ribbon. Furthermore, base plate 10 and joint 11 may be dispensed with, and conductor pattern 14 may function as base plate 10.

An Effect of power module 1 according to the present embodiment will now be described. Power module 1 according to the present embodiment comprises circuit board 12, semiconductor device 30, terminal 40, and a first conductive connection member (conductive connection member 52). Circuit board 12 includes insulating layer 13 having major surface 13b and conductive circuit pattern 15 provided on major surface 13b. Semiconductor device 30 is joined to conductive circuit pattern 15. Conductive circuit pattern 15 includes a first conductive pattern (conductive pattern 20). Terminal 40 includes first end 41. First end 41 of terminal 40 includes first surface 42 joined to the first conductive pattern and second surface 43 opposite to first surface 42. The first conductive connection member bridges second surface 43 of terminal 40 and the first conductive pattern.

Power module 1 has terminal 40 electrically connected to the first conductive pattern not only by joint 45 between first surface 42 of terminal 40 and the first conductive pattern (conductive pattern 20) but also by the first conductive connection member (conductive connection member 52). Therefore, even if joint 45 peels off the first conductive pattern, terminal 40 is still electrically connected to the first conductive pattern through the first conductive connection member. This enhances power module 1 in reliability.

Terminal 40 is not joined to semiconductor device 30 and instead joined to the first conductive pattern (conductive pattern 20). This can suppress an increase in time and effort in manufacturing for joining terminal 40 even when the number of semiconductor devices 30 is increased in order to increase power module 1 in capacity. This allows power module 1 to be manufactured more efficiently.

The first conductive connection member (conductive connection member 52) is joined to terminal 40 on second surface 43 of terminal 40 opposite to first surface 42 of terminal 40 joined to the first conductive pattern (conductive pattern 20). This allows terminal 40 and hence power module 1 to be miniaturized.

Power module 1 according to the present embodiment has the first conductive connection member (conductive connection member 52) in the form of a conductive wire or a conductive ribbon.

Therefore, even if joint 45 between first surface 42 of terminal 40 and the first conductive pattern (conductive pattern 20) peels off the first conductive pattern (conductive pattern 20), terminal 40 is still electrically connected to the first conductive pattern through the first conductive connection member (conductive connection member 52). This enhances power module 1 in reliability.

Power module 1 according to the present embodiment has the first conductive pattern (conductive pattern 20), terminal 40, and the first conductive connection member (conductive connection member 52) formed of copper (Cu).

With the first conductive pattern (conductive pattern 20) and terminal 40 formed of copper (Cu), even when the first conductive connection member (conductive connection member 52) is formed of copper (Cu) having larger strength than aluminum, the first conductive connection member can be satisfactorily joined or bonded to the first conductive pattern and terminal 40. The first conductive connection member formed of a material larger in strength and higher in reliability enhances power module 1 in reliability.

The method for manufacturing power module 1 according to the present embodiment comprises preparing circuit board 12 (S1). Circuit board 12 includes insulating layer 13 having major surface 13b and conductive circuit pattern 15 provided on major surface 13b. Conductive circuit pattern 15 includes the first conductive pattern (conductive pattern 20). The method for manufacturing power module 1 according to the present embodiment comprises joining semiconductor device 30 to conductive circuit pattern 15 (S2), and joining terminal 40 to the first conductive pattern (S4). Terminal 40 includes first end 41. First end 41 of terminal 40 includes first surface 42 joined to the first conductive pattern and second surface 43 opposite to first surface 42. The method for manufacturing power module 1 according to the present embodiment includes bridging second surface 43 of terminal 40 and the first conductive pattern with the first conductive connection member (S7).

Therefore, even if joint 45 between first surface 42 of terminal 40 and the first conductive pattern (conductive pattern 20) peels off the first conductive pattern (conductive pattern 20), terminal 40 is still electrically connected to the first conductive pattern through the first conductive connection member (conductive connection member 52). This enhances power module 1 in reliability.

### Second Embodiment

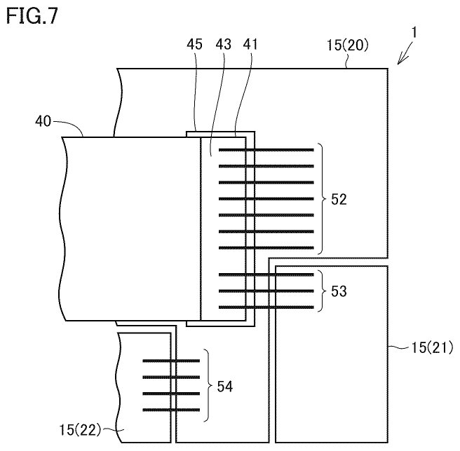

Power module 1 according to a second embodiment will now be described with reference to FIG. 7. While power module 1 according to the present embodiment has a configuration similar to that of power module 1 of the first embodiment and achieves an effect similar to that thereof, the power module according to the present embodiment differs from that of the first embodiment mainly as follows.

Conductive circuit pattern 15 further includes a conductive pattern 21 and a conductive pattern 22. Conductive patterns 20, 21, and 22 are spaced from one another. Conductive patterns 21 and 22 may be spaced from that portion of conductive circuit pattern 15 to which semiconductor devices 30 and 31 are joined. Conductive pattern 20 is for example a joining conductive pad to which terminal 40 is joined. Conductive patterns 21 and 22 are, for example, inspecting conductive pads.

Power module 1 according to the present embodiment further comprises conductive connection members 53 and 54. Conductive connection member 53 bridges conductive pattern 21 and second surface 43 of first end 41 of terminal 40. Conductive connection member 53 is for example a conductive wire bonded to conductive pattern 21 and second surface 43 of first end 41 of terminal 40. Conductive connection member 54 bridges conductive patterns 20 and 22. Conductive connection member 54 is for example a conductive wire bonded to conductive patterns 20 and 22.

A function of power module 1 according to the present embodiment will now be described. Joint 45 has a joint area larger than that between terminal 40 and conductive connection member 52 and that between conductive connection member 52 and conductive pattern 20. When there is no crack in joint 45, the electrical resistance between terminal 40 and conductive pattern 20 via joint 45 is smaller than that between terminal 40 and conductive pattern 20 via conductive connection member 52. Conductive pattern 20 is electrically connected to conductive pattern 21 through joint 45, conductive connection member 52, first end 41 of terminal 40, and conductive connection member 53. When a crack develops in joint 45, the electrical resistance between conductive patterns 20 and 21 increases. Monitoring the electrical resistance between conductive patterns 20 and 21 allows detection of deterioration of joint 45 (or to what extent a crack develops therein).

Furthermore, conductive pattern 21 is electrically connected to conductive pattern 22 through conductive connection member 53, first end 41 of terminal 40, joint 45, conductive pattern 20, and conductive connection member 54. Therefore, when a crack develops in joint 45, the electrical resistance between conductive patterns 21 and 22 also increases. Monitoring the electrical resistance between conductive patterns 21 and 22 allows detection of deterioration of joint 45 (or to what extent a crack develops therein).

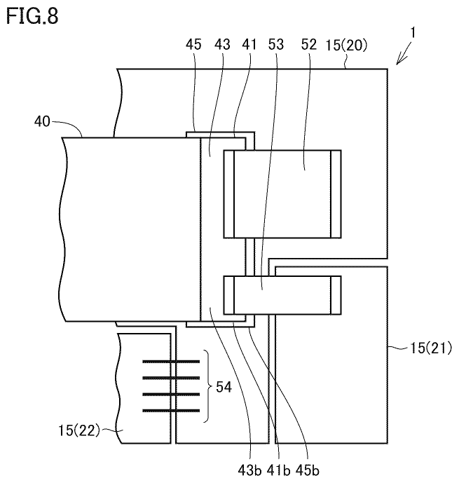

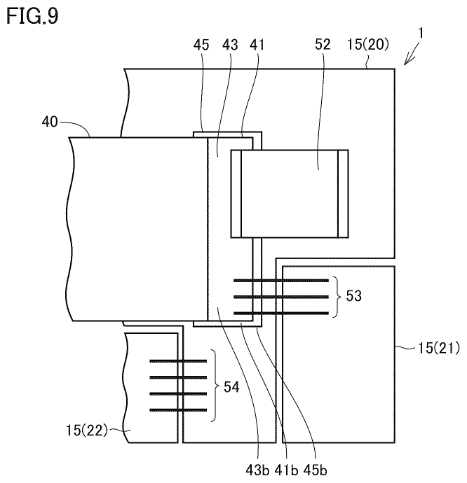

In a variation of the present embodiment, at least one of conductive connection members 52, 53, and 54 may be a conductive ribbon. For example, as shown in FIG. 8, conductive connection members 52 and 53 may be conductive ribbons, and conductive connection member 54 may be a conductive wire. As shown in FIG. 9, conductive connection member 52 may be a conductive ribbon, and conductive connection members 53 and 54 may be conductive wires. Conductive connection members 52, 53, and 54 may be conductive ribbons.

In addition to an effect of power module 1 of the first embodiment, power module 1 according to the present embodiment has the following effect.

Power module 1 according to the present embodiment further comprises a second conductive connection member (conductive connection member 53). Conductive circuit pattern 15 includes a second conductive pattern (conductive pattern 21) spaced from the first conductive pattern (conductive pattern 20). The second conductive connection member bridges second surface 43 of terminal 40 and the second conductive pattern.

Monitoring the electrical resistance between the first conductive pattern (conductive pattern 20) and the second conductive pattern (conductive pattern 21) allows detection of deterioration of joint 45 (or to what extent a crack develops therein).

Power module 1 according to the present embodiment further comprises a third conductive connection member (conductive connection member 54). Conductive circuit pattern 15 includes a third conductive pattern (conductive pattern 22) spaced from the first conductive pattern (conductive pattern 20) and the second conductive pattern (conductive pattern 21). The third conductive connection member bridges the first conductive pattern and the third conductive pattern.

Monitoring the electrical resistance between the second conductive pattern (conductive pattern 21) and the third conductive pattern (conductive pattern 22) allows detection of deterioration of joint 45 between first surface 42 of terminal 40 and the first conductive pattern (conductive pattern 20) (or to what extent a crack develops in the joint).

### Third Embodiment

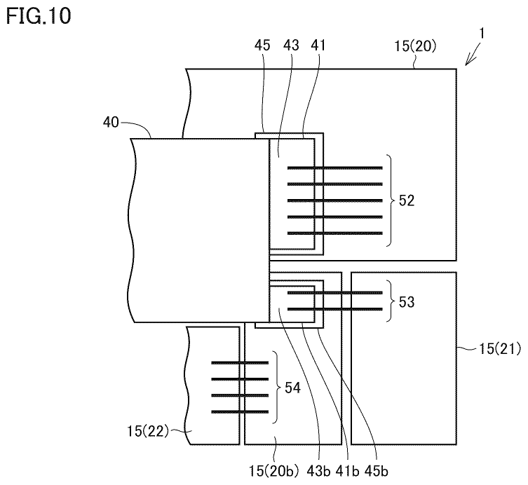

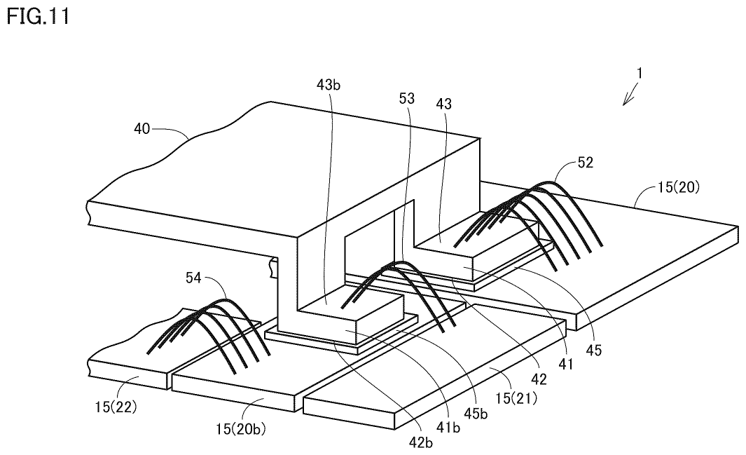

Power module 1 according to a third embodiment will now be described with reference to FIGS. 10 and 11. While power module 1 according to the present embodiment has a configuration similar to that of power module 1 of the first embodiment and achieves an effect similar to that thereof, the power module according to the present embodiment differs from that of the first embodiment mainly as follows.

Conductive circuit pattern 15 further includes a conductive pattern 20b, conductive pattern 21, and conductive pattern 22. Conductive patterns 20, 20b, 21, and 22 are spaced from one another. Conductive patterns 20b, 21, and 22 may be spaced from that portion of conductive circuit pattern 15 to which semiconductor devices 30 and 31 are joined. Conductive patterns 20 and 20b are, for example, joining conductive pads to which terminal 40 are joined. Conductive patterns 21 and 22 are, for example, inspecting conductive pads.

Terminal 40 further includes a second end 41b. Second end 41b is spaced from first end 41 and is adjacent to first end 41. First end 41 and second end 41b are ends of terminal 40 that are proximal to circuit board 12. Second end 41b of terminal 40 includes a third surface 42b and a fourth surface 43b opposite to third surface 42b. Terminal 40 has third surface 42b joined to conductive pattern 20b at a joint 45b. Joint 45b may be formed for example of solder, a fine silver particulate sintered compact or a similar fine metallic particulate sintered compact, or a conductive filler-containing resin or the like, or may be liquid phase diffusion bonding between third surface 42b of terminal 40 and conductive pattern 20b. Joint 45b may be identical to joint 45.

Power module 1 according to the present embodiment further comprises conductive connection members 53 and 54. Conductive connection member 53 bridges conductive pattern 21 and fourth surface 43b of second end 41b of terminal 40. Conductive connection member 53 is for example a conductive wire bonded to conductive pattern 21 and fourth surface 43b of second end 41b of terminal 40. Conductive connection member 54 bridges conductive patterns 20b and 22. Conductive connection member 54 is for example a conductive wire bonded to conductive patterns 20b and 22.

A function of power module 1 according to the present embodiment will now be described. In the present embodiment, monitoring the electrical resistance between two of conductive patterns 20, 21, and 22 allows detection of deterioration of joint 45 (or to what extent a crack develops therein) or deterioration of joint 45b (or to what extent a crack develops therein).

Specifically, joint 45 has a joint area larger than that between terminal 40 and conductive connection member 52 and that between conductive connection member 52 and conductive pattern 20. When there is no crack in joint 45, the electrical resistance between terminal 40 and conductive pattern 20 via joint 45 is smaller than that between terminal 40 and conductive pattern 20 via conductive connection member 52. Conductive pattern 20 is electrically connected to conductive pattern 21 through joint 45, conductive connection member 52, first end 41 of terminal 40, second end 41b of terminal 40, and conductive connection member 53. When a crack develops in joint 45, the electrical resistance between conductive patterns 20 and 21 increases. Monitoring the electrical resistance between conductive patterns 20 and 21 allows detection of deterioration of joint 45 (or to what extent a crack develops therein).

Furthermore, conductive pattern 20 is electrically connected to conductive pattern 22 through joint 45, conductive connection member 52, first end 41 of terminal 40, second end 41b of terminal 40, joint 45b, conductor pattern 20b, and conductive connection member 54. Therefore, when a crack develops in at least one of joint 45 or 45b, the electrical resistance between conductive patterns 20 and 22 increases. Monitoring the electrical resistance between conductive patterns 20 and 22 allows detection of deterioration of at least one of joint 45 or 45b (or to what extent a crack develops therein).

Conductive pattern 21 is electrically connected to conductive pattern 22 through conductive connection member 53, second end 41b of terminal 40, joint 45b, conductor pattern 20b, and conductive connection member 54. Therefore, when a crack develops in joint 45b, the electrical resistance between conductive patterns 21 and 22 increases. Monitoring the electrical resistance between conductive patterns 21 and 22 allows detection of deterioration of joint 45b (or to what extent a crack develops therein).

In a variation of the present embodiment, at least one of conductive connection members 52, 53, and 54 may be a conductive ribbon.

In addition to an effect of power module 1 of the first embodiment, power module 1 according to the present embodiment has the following effect.

Power module 1 according to the present embodiment further comprises the second conductive connection member (conductive connection member 53) and the third conductive connection member (conductive connection member 54). Conductive circuit pattern 15 includes the second conductive pattern (conductive pattern 20b), the third conductive pattern (conductive pattern 21), and a fourth conductive pattern (conductive pattern 22). The first conductive pattern (conductive pattern 20), the second conductive pattern, the third conductive pattern, and the fourth conductive pattern are spaced from one another. Terminal 40 includes second end 41b spaced from first end 41 and adjacent to first end 41. Second end 41b of terminal 40 includes third surface 42b joined to the second conductive pattern and fourth surface 43b opposite to third surface 42b. The second conductive connection member bridges fourth surface 43b and the third conductive pattern. The third conductive connection member bridges the second conductive pattern and the fourth conductive pattern.

Therefore, monitoring the electrical resistance between two of the first conductive pattern (conductive pattern 20), the third conductive pattern (conductive pattern 21), and the fourth conductive pattern (conductive pattern 22) allows detection of deterioration of joint 45 between first surface 42 of terminal 40 and the first conductive pattern (conductive pattern 20) (or to what extent a crack develops in the joint) or deterioration of joint 45b between third surface 42b of terminal 40 and the second conductive pattern (conductive pattern 20b) (or to what extent a crack develops in the joint).

### Fourth Embodiment

The present embodiment applies any one of power modules 1 of the first to third embodiments and their variations to a power conversion apparatus. Although the present disclosure is not limited to a specific power conversion apparatus, hereinafter as a fourth embodiment will be described any one of power modules 1 of the first to third embodiments and their variations to applied to a three-phase inverter.

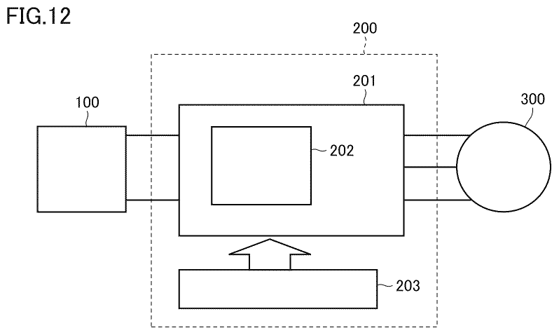

FIG. 12 shows a power conversion system, which is composed of a power supply 100, a power conversion apparatus 200, and a load 300. Power supply 100 is a DC power supply and supplies DC power to power conversion apparatus 200. Although not particularly limited, power supply 100 may for example include a DC system, a solar battery or a storage battery, or may include a rectifier circuit or an AC/DC converter connected to an AC system. Power supply 100 may include a DC/DC converter that receives DC power output from a DC system and converts the received DC power to prescribed power.

Power conversion apparatus 200 is a three-phase inverter connected between power supply 100 and load 300, and receives DC power supplied from power supply 100, converts the received DC power to AC power and supplies the AC power to load 300. As shown in FIG. 12, power conversion apparatus 200 comprises a main conversion circuit 201 that converts DC power to AC power and outputs the AC power, and a control circuit 203 that outputs a control signal to main conversion circuit 201 to control main conversion circuit 201.

Load 300 is a three-phase electric motor driven by AC power supplied from power conversion apparatus 200. Note that load 300 is not limited to a specific application; rather, it is an electric motor mounted on a variety of types of electric devices and is used for example as an electric motor for a hybrid vehicle, an electric vehicle, a railroad vehicle, an elevator, or an air-conditioning device.

Hereinafter, power conversion apparatus 200 will be described in detail. Main conversion circuit 201 comprises a switching device (not shown) and a freewheeling diode (not shown). Main conversion circuit 201 receives DC power supplied from power supply 100, and as the switching device switches voltage supplied from power supply 100, main conversion circuit 201 converts the DC power to AC power, and supplies the AC power to load 300. While there are a variety of types of specific circuit configurations for main conversion circuit 201, main conversion circuit 201 according to the present embodiment is a two-level three-phase fullbridge circuit, and may include six switching devices and six freewheeling diodes anti-parallel to their respective switching devices. As each switching device and each freewheeling diode of main conversion circuit 201, semiconductor devices 30 and 31 included in any one of power modules 1 of the first to third embodiments and their variations are applicable. As a power module 202 constituting main conversion circuit 201, any one of power modules 1 of the first to third embodiments and their variations is applicable. The six switching devices have every two thereof connected in series to configure a vertical arm, and each vertical arm configures one of phases (a U phase, a V phase, and a W phase) of the fullbridge circuit. Each vertical arm has an output terminal, that is, main conversion circuit 201 has three output terminals, connected to load 300.

Furthermore, main conversion circuit 201 includes a drive circuit (not shown) to drive each switching device. The drive circuit may be incorporated in power module 202 or may be provided outside power module 202. The drive circuit generates a drive signal for driving the switching devices included in main conversion circuit 201, and supplies the drive signal to a control electrode of each switching device of main conversion circuit 201. Specifically, in response to a control signal issued from control circuit 203, a drive signal for turning on a switching device and a drive signal for turning off a switching device are output to the control electrode of each switching device.

Control circuit 203 controls the switching devices of main conversion circuit 201 so as to supply power to load 300. Specifically, a time (an ON time) for which each switching device of main conversion circuit 201 should be turned on is calculated based on power to be supplied to load 300. For example, main conversion circuit 201 can be controlled by PWM control which modulates an ON time of the switching device depending on the voltage to be output to load 300. A control command (a control signal) is output to the drive circuit that main conversion circuit 201 comprises so that an ON signal is output to a switching device to be turned on at each time point and an OFF signal is output to a switching device to be turned off at the time point. The drive circuit operates in response to this control signal to output the ON signal or the OFF signal as a drive signal to the control electrode of each switching device.

In power conversion apparatus 200 according to the present embodiment, any one of power modules 1 of the first to third embodiments and their variations is applied as power module 202 included in main conversion circuit 201. Therefore, power conversion apparatus 200 according to the present embodiment is improved in reliability.

While an example in which the present disclosure is applied to a two-level three-phase inverter has been described in the present embodiment, this is not exclusive, and the present disclosure is applicable to a variety of types of power conversion apparatuses. While the present embodiment is applied to a two-level power conversion apparatus, it may be applied to a three-level power conversion apparatus or a multi-level power conversion apparatus. When the power conversion apparatus supplies power to a single-phase load, the present disclosure may be applied to a single-phase inverter. When the power conversion apparatus supplies power to a DC load or the like, the present disclosure may be applied to a DC/DC converter or an AC/DC converter.

A power conversion apparatus to which the present disclosure is applied is not limited to a case where a load is an electric motor, and may be incorporated for example into a power supply apparatus for an electric spark machine or a laser beam machine, or a power supply apparatus for an induction heating cooker or a wireless power transfer system. A power conversion apparatus to which the present disclosure is applied may further be used as a power conditioner for a photovoltaic power generation system, a power storage system or the like.

It should be understood that the first to fourth embodiments and their variations disclosed herein are illustrative and non-restrictive in any respect. Insofar as there is no contradiction, at least two of the first to fourth embodiments and their variations disclosed herein may be combined together. The scope of the present disclosure is not defined by the above description but by the terms of the claims, and is intended to encompass any modification within the meaning and scope equivalent to the terms of the claims.

### REFERENCE SIGNS LIST

1 power module, 10 base plate, 11, 33, 34, 45, 45b joint, 12 circuit board, 13 insulating layer, 13a, 13b major surface, 14, 20b conductor pattern, 15 conductive circuit pattern, 20, 20b, 21, 22 conductive pattern, 30, 31 semiconductor device, 40 terminal, 41 first end, 41b second end, 42 first surface, 42b third surface, 43 second surface, 43b fourth surface, 50, 51, 52, 53, 54 conductive connection member, 60 casing, 61 sealing member, 100 power supply, 200 power conversion apparatus, 201 main conversion circuit, 202 power module, 203 control circuit, 300 load.

1. A power module comprising:
a circuit board including an insulating layer having a major surface, and a conductive circuit pattern provided on the major surface;
a semiconductor device joined to the conductive circuit pattern;
a terminal including a first end; and
a first conductive connection member,
the conductive circuit pattern including a first conductive pattern,
the first end of the terminal including a first surface joined to the first conductive pattern and a second surface opposite to the first surface,
the first conductive connection member bridging the second surface and the first conductive pattern.

2. The power module according to claim 1, further comprising a second conductive connection member, wherein
the conductive circuit pattern includes a second conductive pattern spaced from the first conductive pattern, and
the second conductive connection member bridges the second surface and the second conductive pattern.

3. The power module according to claim 2, further comprising a third conductive connection member, wherein
the conductive circuit pattern includes a third conductive pattern spaced from the first conductive pattern and the second conductive pattern, and
the third conductive connection member bridges the first conductive pattern and the third conductive pattern.

4. The power module according to claim 1, further comprising:
a second conductive connection member; and
a third conductive connection member, wherein
the conductive circuit pattern includes a second conductive pattern, a third conductive pattern and a fourth conductive pattern, and the first conductive pattern, the second conductive pattern, the third conductive pattern, and the fourth conductive pattern are spaced from one another,
the terminal includes a second end spaced from the first end and adjacent to the first end,
the second end of the terminal includes a third surface joined to the second conductive pattern and a fourth surface opposite to the third surface,
the second conductive connection member bridges the fourth surface and the third conductive pattern, and
the third conductive connection member bridges the second conductive pattern and the fourth conductive pattern.

5. The power module according to claim 1, wherein the first conductive connection member is a conductive wire or a conductive ribbon.

6. The power module according to claim 1, wherein the first conductive pattern, the terminal, and the first conductive connection member are formed of copper.

7. A method for manufacturing a power module, comprising:
preparing a circuit board including an insulating layer having a major surface, and a conductive circuit pattern provided on the major surface, the conductive circuit pattern including a first conductive pattern;
joining a semiconductor device to the conductive circuit pattern;
joining a terminal to the first conductive pattern, the terminal including a first end, the first end of the terminal including a first surface joined to the first conductive pattern and a second surface opposite the first surface; and
bridging the second surface and the first conductive pattern with a first conductive connection member.

8. A power conversion apparatus comprising:
a main conversion circuit having the power module according to claim 1 to convert received power and output the converted power; and
a control circuit to output a control signal to the main conversion circuit to control the main conversion circuit.
